(19) United States
(12) Patent Application Publication
(10) Pub. No.: US 2008/0173828 A1
(43) Pub. Date: Jul. 24, 2008

(54) Ion implantation device and method for implanting ions

(75) Inventors: Katsuhiro Ohno, Ichinomiya-city (JP); Koji Matsumoto, Nagoya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/007,392

(22) Filed: Jan. 10, 2008

(30) Foreign Application Priority Data
Jan. 19, 2007 (JP) 2007-9767
Nov. 30, 2007 (JP) 2007-310460

(51) Int. Cl. H01J 37/147; H01J 37/08

(52) U.S. Cl. 250/396 ML; 250/492.3

(57) ABSTRACT

An ion implantation device includes: an ion source for retrieving an ion beam; a passage for passing the ion beam therethrough; a mass analysis magnet for selecting a predetermined ion species from the ion beam, the mass analysis magnet disposed in the passage; an implantation chamber for implanting the predetermined ion species in a target with the ion beam output from the mass analysis magnet; and an inner pressure controller for introducing an gas into the passage and for controlling an inner pressure of the passage. Since the above device includes the inner pressure controller, a concentration profile of the implanted ions in the target is appropriately controlled.

### CROSS REFERENCE TO RELATED APPLICATIONS

This application is based on Japanese Patent Applications No. 2007-9767 filed on Jan. 19, 2007, and No. 2007-310460 filed on Nov. 30, 2007, the disclosures of which are incorporated herein by reference.

### FIELD OF THE INVENTION

The present invention relates to an ion implantation device and a method for implanting ions.

### BACKGROUND OF THE INVENTION

An ion implantation device implants ions in a predetermined position of a specimen as a target such as a semiconductor substrate. The device includes an ion source for ionizing atoms and retrieving an ion beam, a mass analysis magnet for selecting a specific ion species from the ion beam, and a passage for passing, accelerating and scanning the ion beam.

The ion beam retrieved from the ion source passes through the passage, which is maintained in high vacuum. The specific ion species is selected by the mass analysis magnet. Then, the ion beam is irradiated on the target. Thus, the specific ion species is implanted in the target.

An ion implantation device is disclosed in JP-B1-3769444. The device includes an ion source, an ion acceleration tube connecting to the ion source, an evacuate element for evacuating the ion source, an air tight box for accommodating the evacuate element and a portion from the ion source to the ion acceleration tube, the air tight box connecting to a voltage application electrode on an inlet of an ion acceleration tube side, and a shield cabinet for accommodating the box, the cabinet is electrically insulated from the box, connects to another voltage application electrode on an outlet of the ion acceleration tube side, and is grounded.

In the above ion implantation device, the vacuum degree in the passage and the resolution of the ion depend on performance and arrangement of a vacuum pump for evacuating the passage and on a construction of a separation slit for removing excess ions from the ion beam. Thus, concentration profile of the ion implanted in the target depends on each ion implantation device even when the ions are implanted under the same condition.

In this case, device characteristics in case of high vacuum degree are deviated from those in case of low vacuum degree.

Thus, it is difficult to control the concentration profile of impurities. Further, it is required to select a certain ion implantation device having a certain concentration profile according to a product. Thus, a manufacturing cost of the product becomes larger.

### SUMMARY OF THE INVENTION

In view of the above-described problem, it is an object of the present disclosure to provide an ion implantation device and a method for implanting ions.

According to a first aspect of the present disclosure, an ion implantation device includes: an ion source for retrieving an ion beam; a passage for passing the ion beam therethrough; a mass analysis magnet for selecting a predetermined ion species from the ion beam, the mass analysis magnet disposed in the passage; an implantation chamber for implanting the predetermined ion species in a target with the ion beam output from the mass analysis magnet; and an inner pressure controller for introducing an gas into the passage and for controlling an inner pressure of the passage.

Since the above device includes the inner pressure controller, a concentration profile of the implanted ions in the target is appropriately controlled.

According to a second aspect of the present disclosure, a method for implanting ions into a target includes: retrieving an ion beam from an ion source; passing the ion beam through a passage; selecting a predetermined ion species from the ion beam with a mass analysis magnet, wherein the magnet is disposed in the passage; accelerating and decelerating the ion beam with an acceleration and deceleration tube, the ion beam retrieved from the magnet; implanting the predetermined ion species into the target, which is disposed in an implantation chamber; and introducing a gas into the passage and controlling an inner pressure of the passage with an inner pressure controller. The implanting the predetermined ion species is performed after the introducing the gas and controlling the inner pressure.

Since the above method includes the introducing the gas into the passage and controlling the inner pressure of the passage with the inner pressure controller, a concentration profile of the implanted ions in the target is appropriately controlled.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic view showing an ion implantation device;

FIG. 2 is a graph showing a relationship between an inner pressure of a passage and a concentration profile of implanted ions;

FIG. 3 is a schematic view showing an inner pressure controller connecting to a magnet region; and

FIG. 4 is a graph showing a concentration profile of various ion implantation devices having different vacuum degrees.

### DETAILED DESCRIPTION OF THE PREFERRED EMBODIMENTS

The inventors preliminarily studies about ion implantation.

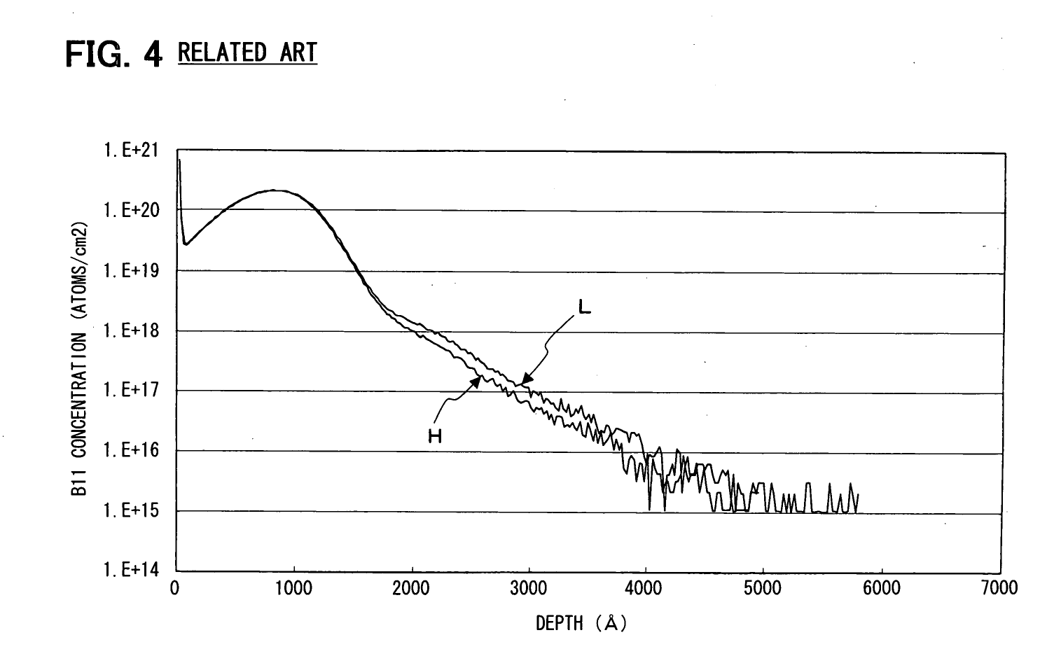

FIG. 4 shows an example of a concentration profile of implanted ions in a semiconductor substrate when vacuum degrees in a passage of an ion beam are different. H represents a high vacuum degree of the passage, and L represents a low vacuum degree of the passage. A BF₂⁺ ion species is implanted in the semiconductor substrate. A horizontal axis in FIG. 4 represents a depth from the surface of the substrate, and a vertical axis represents a concentration of boron ions.

A difference of the concentration profile between the high vacuum degree and the low vacuum degree arises from a depth of 150 nm. When the vacuum degree is high, the concentration profile of the boron ions becomes lower, compared with the case of the low vacuum concentration. This difference is attributed from the following reason.

The ion beam including the BF₂⁺ ions selected by a mass analysis magnet is transmitted through the passage toward the semiconductor substrate. During the passage, the ion beam collides with a residual gas atom in the passage, so that a part of the BF₂⁺ ions is dissociated. Thus, for example, a B⁺ ion is formed. Thus, the ion beam includes not only the BF₂⁺ ions but also the B⁺ ions.

The amount of the B⁺ ions generated from the BF₂⁺ ions depends on the vacuum degree in the passage. When the vacuum degree is low, the collision provability between the ion beam and the residual gas atoms becomes higher. Accordingly, the BF₂⁺ ions are easily dissociated, and the amount of the B⁺ ions in case of the low vacuum degree becomes larger than the case of the high vacuum degree.

The mass of the B⁺ ion is smaller than that of the BF₂+ion. Therefore, the B⁺ ion is easily implanted in a deep region from the surface of the semiconductor substrate. When the vacuum degree in the passage is low, the amount of the B⁺ ions in the region deeper than 150 nm becomes larger than the case of the high vacuum degree. Accordingly, the above difference of concentration profile between the case of high vacuum degree and the case of low vacuum degree arises.

In view of the above reason, the inventors provide a following ion implantation device and a method for implanting ions.

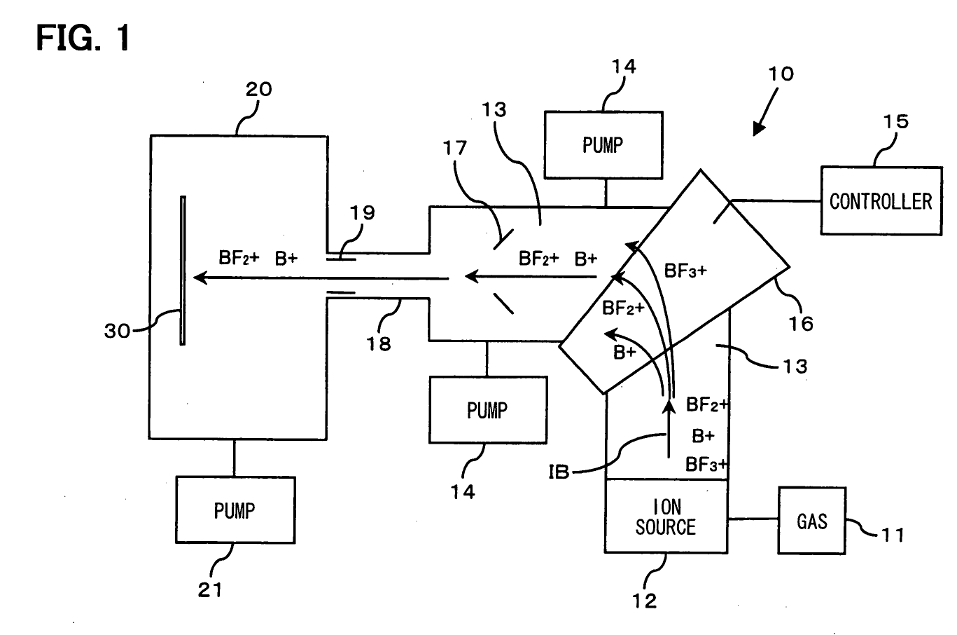

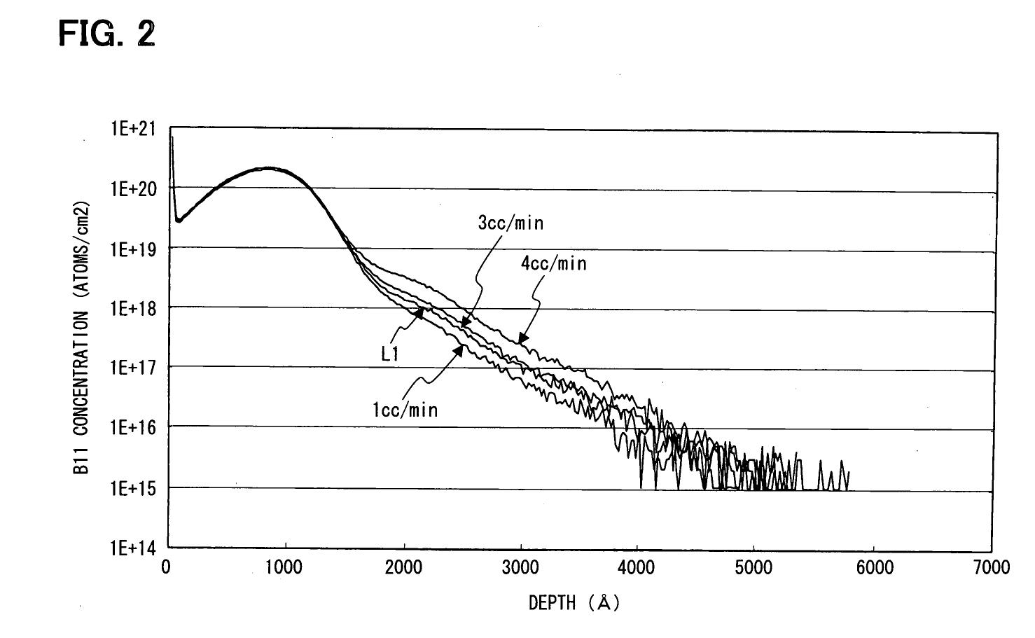

FIG. 1 shows an ion implantation device 10, and FIG. 2 shows a relationship between an inner pressure of a passage 13 of an ion beam and a concentration profile of implanted ions. Here, the beam current of the ion beam is about a few tens mA or smaller, so that the ion implantation device 10 is a large current ion implantation device 10.

The device 10 includes a gas bottle 11, an ion source 12, the passage 13, a vacuum pump 14, an inner pressure controller 15, a mass analysis magnet 16, a variable aperture 17, an acceleration/deceleration tube 18, a Faraday cup 19, an implantation chamber 20 and another vacuum pump 21. The gas bottle 11 supplies a raw material gas, which provides ions to be implanted in a target. The ion source 12 generates a raw material gas plasma, and retrieves the plasma as an ion beam IB by applying a voltage to a retrieve electrode. The ion beam IB passes through the passage 13. The vacuum pump 14 evacuates the passage 13. The inner pressure control device 15 introduces another gas in the passage so that the control device 15 controls the inner pressure of the passage. The mass analysis magnet 16 selects a specific ion species from the ion beam IB. The variable aperture 17 shields a part of the ion beam IB introduced from the magnet 16, so that the aperture 17 adjusts the ion beam IB. The acceleration/deceleration tube 18 accelerates or decelerates the ion beam IB to have a predetermined energy. The Faraday cup 19 counts the number of ions to be implanted in the target. The implantation chamber 20 holds and scans the target, i.e., the semiconductor substrate 30, so that the target is implanted with the ions. The other vacuum pump 21 evacuates the implantation chamber 20.

The inner pressure controller 15 is connected to the passage 13 at a portion near the magnet 16. The controller 15 introduces a gas into the passage 13 with controlling a flow rate of the gas, which does not interact with the ion beam IB and is not ionized by the ion source 12. The controller 15 controls the inner pressure of the passage 13. For example, the controller 15 introduces the gas with the flow rate of a few cc/min, so that the inner pressure (i.e., an inert gas pressure) of the passage 13 is controlled in a range between 10⁻⁵ Torr and 10⁻⁶ Torr. The gas may be an inert gas such as a nitrogen gas, a He gas, a Ar gas a Xe gas. Alternatively, the gas may be a mixed gas of the inert gases.

The variable aperture 17 shields a part of the ion beam IB so that the aperture 17 adjusts the ion beam IB. By adjusting a width of the aperture 17 for passing the ion beam IB, the shielding amount of the ion beam IB is controlled. Thus, unwanted ion species are removed from the ion beam IB so that the ion beam IB only includes the specific ion species. Further, the irradiation amount of the ion beam IB is adjusted.

A method for implanting ions by using the ion implantation device 10 is explained as follows. For example, the BF₂⁺ ion and the B⁺ ion are implanted in the substrate 30.

First, the BF₃ gas as a raw material gas is introduced from the gas bottle 11 into the ion source 12. Then, the BF₃ gas is ionized by the ion source 12 so that the BF₃ plasma is generated. By applying a negative potential to a retrieve electrode, the ion beam IB is retrieved from the ion source 12. At this moment, the ion beam IB includes a BF₂⁺ ion species, a BF⁺ ion species, a B⁺ ion species, a B₂⁺ ion species, a B⁺⁺ ion species and the like.

Then, the inner pressure controller 15 introduces the nitrogen gas into the passage 13 with a flow rate of, for example, 3 cc/min. The controller 15 controls the inner pressure of the passage 13. In the passage 13, balance between introduction of the nitrogen gas from the controller 15 and evacuation by the vacuum pump 14 provides the inner pressure of 1.0×10⁻⁵ Torr. Here, a vacuum gauge (not shown) may detect the inner pressure so that the flow rate of the nitrogen gas is controlled based on an output from the vacuum gauge.

The ion beam IB retrieved from the ion source 12 is transmitted through the passage 13. Then, the mass analysis magnet 16 bends the ion beam IB so that the mass of the ion beam IB is analyzed. Thus, the BF₂⁺ ions are selected.

The ion beam IB passed through the magnet 16 mainly includes the BF₂⁺ ions. The ion beam IB is transmitted in the passage 13 toward the implantation chamber 20. In the passage 13, the BF₂⁺ ions collide with the nitrogen atoms, so that a part of the BF₂⁺ ions is dissociated. Thus, the B⁺ ions are generated. Further, the BF₂⁺ ions are neutralized so that B atoms are also generated.

The amount of the B⁺ ions depends on the vacuum degree of the passage 13. When the vacuum degree of the passage 13 is low, the collision provability between the ion beam and the nitrogen gas atoms becomes higher. Accordingly, the BF₂⁺ ions are easily dissociated, and the amount of the B⁺ ions in case of the low vacuum degree becomes larger than the case of the high vacuum degree. Further, the amount of the neutralized B atoms also increases.

The ion beam IB including the BF₂⁺ ions and the B⁺ ions passes through the variable aperture 17. Then, the acceleration/deceleration tube 18 accelerates or decelerates the ion beam IB so as to have a predetermined energy, and the ion beam IB is irradiated on the semiconductor substrate 30 in the implantation chamber 20. The substrate 30 is displaced so that the ion beam IB scans on the substrate 30. Thus, the ion implantation is performed on the substrate 30 with high homogeneous distribution.

The aperture width of the aperture 17 is controlled so that the amount of B⁺ ions to be irradiated on the substrate 30 is controlled. For example, when the aperture width is sufficiently large so that the B⁺ ions are not cut off, the irradiation of the B⁺ ions is not limited.

The ion implantation device 10 includes the inner pressure controller 15, which introduces the nitrogen gas in the passage 13 of the ion beam IB, and the nitrogen gas atoms are disposed on a trajectory of the ion beam IB. The ion beam IB collides with the nitrogen atoms, so that the BF₂⁺ ions are dissociated. Thus, the B⁺ ions are generated. Thus, the vacuum degree of the passage 13 is controlled. Here, in this case, the vacuum degree is comparatively low, which corresponds to the curve L in FIG. 4. Thus, the ion beam IB having the low vacuum degree is reproducibly provided.

Next, when the flow rate of the nitrogen gas to be introduced into the passage 13 is changed so as to change the inner pressure of the passage 13, the concentration profile of the boron atoms in the semiconductor substrate 30 is also changed as shown in FIG. 2. In FIG. 2, the horizontal axis represents the depth from the surface of the substrate 30, and the vertical axis represents the concentration of the boron atoms.

The gas flow rate is 1 cc/min, 3 cc/min or 4 cc/min. L1 represents another ion implantation device having vacuum degree of a passage for an ion beam, the vacuum degree which is lower than that in the ion implantation device 10.

When the gas flow rate is 1 cc/min, the inner pressure of the passage 13 is 4.6×10⁻⁶ Torr, when the gas flow rate is 3 cc/min, the inner pressure of the passage 13 is 1.0×10⁻⁵ Torr, and when the gas flow rate is 4 cc/min, the inner pressure of the passage 13 is 2.1×10⁻⁵Torr.

The difference between the concentration profile at the gas flow rate of 1 cc/min and the concentration profile in the ion implantation device L1 begins from the depth of 150 nm from the surface of the substrate 30. The concentration profile at the gas flow rate of 1 cc/min in a region deeper than 150 nm shifts to a lower side from that of the ion implantation device L1.

When the inner pressure of the passage 13 increases, the boron concentration in the region deeper than 150 nm shifts to a higher side from that of the ion implantation device L1. This occurs for the following reason.

When the inner pressure of the passage 13 increases, the collision provability between the ion beam and the nitrogen atoms increases. Thus, the production of the B⁺ ions and the neutralized B atoms dissociated from the BF₂⁺ ions increases. The B⁺ ions having a small mass are easily implanted in the region deeper than 150 nm. When the gas flow rate is 3 cc/min, the concentration profile in the ion implantation device 10 is almost the same as that in the ion implantation device L1.

Thus, by controlling the gas flow rate to be introduced into the passage 13, the inner pressure of the passage 13 is controlled. By controlling the inner pressure, the concentration profile of the B atoms in the substrate 30 is controlled. Further, by controlling the variable aperture 17 and the acceleration/deceleration tube 18, the control degree of freedom in the concentration profile of the B atoms increases.

If an ion implantation device has no inner pressure controller 15, the device does not reproduce the concentration profile in the ion implantation device L1 having low vacuum degree of the passage 13, i.e., the concentration profile does not coincide with the concentration profile in the ion implantation device L1. Accordingly, it is necessary to select a certain ion implantation device having a certain concentration profile corresponding to the concentration profile in the ion implantation device L1.

However, since the ion implantation device 10 includes the inner pressure controller 15, the device 10 reproduces the concentration profile in the ion implantation device L1, i.e., the concentration profile coincides with the concentration profile in the ion implantation device L1. Thus, the device 10 can manufacture the same product as the ion implantation device L1. Further, the device 10 may implant ions with high purity, which does not include impurity such as the B⁺ ion.

The ion implantation device 10 includes the inner pressure controller 15 for controlling the inner pressure of the passage 13 to be a predetermined value by introducing a gas in the passage 13. After the inner pressure controller 15 controls the inner pressure of the passage 13, the device 10 implant ions in the semiconductor substrate 30. Thus, the gas atoms are disposed in the passage 13, which provides a path of the ion beam IB, so that the ion beam IB collides with the gas atoms. Then, the ion is dissociated or neutralized. Thus, the concentration profile of impurities in the substrate 30 is sufficiently controlled.

The gas to be introduced into the passage 13 may be an inert gas such as nitrogen gas, He gas, Ar gas and Xe gas or a mixed gas of the inert gases. In this case, the gas atom does not interact with the ion beam IB, and therefore, the gas is not easily ionized by the ion source 12.

This inner pressure controller 15 is preferably used for a large current ion implantation device since the concentration profile of implanted ions in the large current ion implantation device is easily deviated in accordance with change of the inner pressure in the passage 13.

The variable aperture 17 can control the shielding amount of the ion beam IB. The variable aperture 17 is disposed on the downstream side of the mass analysis magnet 16. Accordingly, ions other than a predetermined ion species can be removed from the ion beam IB. Further, the amount of ions to be irradiated on the substrate 30 can be adjusted by the aperture 17. Thus, the degree of freedom for controlling the concentration profile increases.

The inner pressure controller 15 may be used for a medium current ion implantation device for implant ions with a beam current equal to or smaller than a few hundreds μA. The medium current ion implantation device may include a quadrupole lens, a scanning plate and a dipole lens. The quadrupole lens aligns the ion beam, and is disposed on a downstream side of the acceleration tube. The scanning plate electrically scans the ion beam, and is disposed on the downstream side of the acceleration tube. The dipole lens parallelizes the ion beam by applying electric field so that the ion beam is perpendicularly irradiated on the substrate.

Although the device 10 implants the boron ions, the device 10 may implant a P ion, an As ion and the like. In this case, the raw material gas may be a PF₃ gas, a PH₃ gas or a AsH₃ gas.

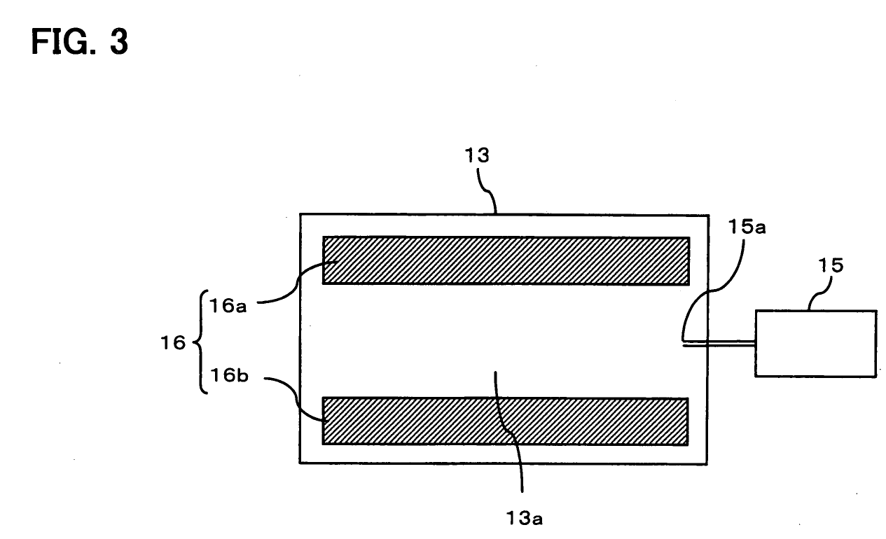

In the device 10, a position at which the inner pressure controller 15 introduces the gas into the passage 13 is near the mass analysis magnet 16. Alternatively, the inner pressure controller 15 may introduce the gas into the passage 13 at another position as long as the inner pressure of the passage 13 is stabilized. For example, as shown in FIG. 3, the inner pressure controller 15 introduces the gas to a region at which the magnet 16 is disposed. The magnet 16 sandwiches the passage 13 up and down. The magnet 16 includes an upper magnet 16a and a lower magnet 16b. The inner pressure controller 15 includes a gas introduction port 15a for introducing the gas into the passage 13. The gas introduction port 15a introduces the gas into a part 13a of the passage 13, which is sandwiched between the upper and lower magnets 16a, 16b. At the part 13a of the passage 13, it is difficult to connect the evacuation pump 14 with the part 13a because of influence of magnetic field and/or electric field of the magnet 16. Thus, the gas introduced into the part 13a is temporarily and stably accumulated in the part 13a. Further, the ion beam IB in the passage, at which the predetermined ion species is selected, collides with the gas.

Thus, the ion beam IB collides with the gas atoms, so that efficiency of dissociation and neutralization is improved. Thus, the efficiency is controlled with high accuracy. By using a small amount of gas, the concentration profile of the impurities in the substrate 30 is controlled with high accuracy.

The gas may be introduced into the part 13a of the passage 13 from the upstream side of the ion beam IB. In this case, the collision provability between the ion beam IB and the gas atoms in the part 13a increases.

Alternatively, the gas may be introduced into the part 13a from a portion, which is disposed on a far side from the evacuation pump 14. In this case, the gas is easily accumulated in the part 13a.

Alternatively, the gas may be introduced from a portion between the magnet 16 and the aperture 17.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. An ion implantation device comprising:
an ion source for retrieving an ion beam;
a passage for passing the ion beam therethrough;
a mass analysis magnet for selecting a predetermined ion species from the ion beam, the mass analysis magnet disposed in the passage;
an implantation chamber for implanting the predetermined ion species in a target with the ion beam output from the mass analysis magnet; and
an inner pressure controller for introducing an gas into the passage and for controlling an inner pressure of the passage.

2. The device according to claim 1, wherein
the inner pressure controller introduces the gas at a part of the passage, the part at which the magnet is disposed.

3. The device according to claim 1, further comprising:
an acceleration and deceleration tube for accelerating and decelerating the ion beam, which is retrieved from the mass analysis magnet, wherein
the acceleration and deceleration tube is disposed between the mass analysis magnet and the implantation chamber.

4. The device according to claim 3, further comprising:
a variable aperture for controlling the ion beam, wherein
the ion source, the passage, the acceleration and deceleration tube, and the implantation chamber are coupled in this order,
the mass analysis magnet and the variable aperture are disposed in the passage, and
the variable aperture is disposed between the mass analysis magnet and the acceleration and deceleration tube.

5. The device according to claim 4, wherein
the gas is a nitrogen gas, a He gas, an Ar gas, a Xe gas, or a mixture gas among the nitrogen gas, the He gas, the Ar gas and the Xe gas,
the mass analysis magnet includes first and second magnets,
the inner pressure controller includes a gas inlet for introducing the gas into the passage, and
the gas inlet is disposed between the first and second magnets.

6. The device according to claim 1, wherein
the ion implantation device is a large current ion implantation device.

7. A method for implanting ions into a target comprising:
retrieving an ion beam from an ion source;
passing the ion beam through a passage;
selecting a predetermined ion species from the ion beam with a mass analysis magnet, wherein the magnet is disposed in the passage;
accelerating and decelerating the ion beam with an acceleration and deceleration tube, the ion beam retrieved from the magnet;
implanting the predetermined ion species into the target, which is disposed in an implantation chamber; and
introducing a gas into the passage and controlling an inner pressure of the passage with an inner pressure controller, wherein
the implanting the predetermined ion species is performed after the introducing the gas and controlling the inner pressure.

8. The method according to claim 7, wherein
the inner pressure controller introduces the gas at a part of the passage, the part at which the magnet is disposed.

9. The method according to claim 7, wherein
the gas is an inert gas.
